(19) United States
(12) Patent Application Publication
(10) Pub. No.: US 2006/0103020 A1
(43) Pub. Date: May 18, 2006

(54) REDISTRIBUTION LAYER AND CIRCUIT STRUCTURE THEREOF

(76) Inventors: Ho-Ming Tong, Taipei (TW); Shin-Hua Chao, Kaohsiung (TW); Chi-Yu Wang, Kaohsiung City (TW); Cherry Mercado Reyes, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,815

(22) Filed: Oct. 31, 2005

(30) Foreign Application Priority Data
Nov. 12, 2004 (TW) 93134617

(51) Int. Cl. H01L 23/48

(52) U.S. Cl. 257/738

(57) ABSTRACT

A circuit structure of a redistribution layer (RDL) is suitable for a chip to define the circuits and the contact window required by the following bump process. The RDL is disposed on the active surface of the chip. The circuit structure of the RDL mainly includes a first titanium layer, a second titanium layer and a conductive layer. Wherein, the conductive layer is made of aluminum; the first titanium layer and the second titanium layer cover the two surfaces of the conductive layer, respectively. The connectivity between the first titanium layer or the second titanium layer and a macromolecule polymer is stronger than the connectivity between the conductive layer and the macromolecule polymer, so that the peeling or crack caused by poor connectivity between the conductive layer and the adjacent dielectric layers are significantly improved thereby.

### CROSS-REFERENCE TO RELATED APPLICATION

This application claims the priority benefit of Taiwan application serial no. 93134617 filed on Nov. 12, 2004. All disclosure of the Taiwan application is incorporated herein by reference.

### BACKGROUND OF THE INVENTION

1. Field of Invention

The present invention relates to multi-layer metal structure, and particularly to an improved redistribution layer (RDL) and circuit structure thereof to enhance the connect reliability between the circuit structure and dielectric layers.

2. Description of the Related Art

Flip Chip Interconnect Technology (hereinafter “FC”) features a plurality of bonding pads in area array mode disposed on the active surface of a chip followed by forming bumps on the bonding pads; after flipping the chip, the bonding pads of the chip are electrically and mechanically connected to contacts of a carrier by means of the bumps, so that the chip is able to electrically connected to the carrier through the bumps, and further to an electronic apparatus via the circuit of the carrier. FC is suitable for a chip package structure with high pin counts. In addition, FC has various advantages such as reducing the chip package area and shortening transmission path length. With the above-described advantages, FC has been widely applied in the field of packaging chip. The most common chip package structures using FC are, for example, flip chip ball grid array (FC/BGA) and flip chip pin grid array (FC/PGA).

Currently, the general bumps include solder bumps, gold bumps, copper bumps, conductive polymer bumps and polymer bumps. Among them, solder bumps are the most popular application. The conventional bonding pad of chip normally is an aluminum pad. Prior to forming a solder bump (or a lead-free bump) on the surface of a bonding pad, an under bump metallurgy (UBM) would be formed on the bonding pad. A process to form an UBM is quite lengthy, wherein a plurality of metal layers is formed in sequence, which includes an adhesion layer comprised of titanium, tungsten, nickel/vanadium, gold, copper and alloy thereof, a barrier layer and a wetting layer. The UBM functions for preventing poor connectivity and separation between a solder bump and a bonding pad. However, an IMC with poor connectivity between a solder bump (or a lead-free bump) and an aluminum pad is likely to occur, which would reduce the reliability of a chip package.

FIG. 1 is a diagram showing a circuit structure and a contact window required by re-defining the following bump process using a redistribution layer (RDL) in the prior art. Referring to FIG. 1, a passivation layer 104 is disposed on an active surface 102 of a chip 100. The passivation layer 104 is formed by deposition of an organic protective material or inorganic protective material and covers the active surface 102 of the chip 100. The portion of the upper surface of the bonding pad uncovered by the passivation layer 104 forms an opening 106. After that, a redistribution layer (RDL) 120 is formed for connecting between the upper surface of the bonding pad 110 and the solder bump 132 defined by a following bump process, wherein a conductive layer 124 of the RDL 120 is made of, for example, aluminum. Both the up and down sides of the conductive layer 124 are protected by dielectric layers 122 and 126 made of macromolecule polymer. The material of the dielectric layers 122 and 126 is, for example, epoxy resin, polyimide (PI) or BCB. On the upper-most dielectric layer 126 there is a contact window 128 formed by, for example, lithography etching or laser drilling, and the contact window serves to electrically connect an under bump metallurgy (UBM) 130 to a solder bump 132 by exposing the conductive layer 124 thereunder.

Particularly note that the connectivity between the conductive layer 124 of the RDL 120 and the dielectric layers 122 and 126 in the prior art is poor, which is likely to generate crack on the connecting surface under the solder bump 132, and consequently peeling between the conductive layer 124 and the adjacent dielectric layers 122 and 126 would occur. As a result, the reliability of a chip package is affected.

### SUMMARY OF THE INVENTION

An object of the present invention is to provide a redistribution layer (RDL), by which the connectivity between the conductive layer and the dielectric layers is improved for enhancing the connecting reliability under the solder bump.

Another object of the present invention is to provide a redistribution layer (RDL), by which the connectivity between the conductive layer and the dielectric layers is improved and peeling occurred between the conductive layer and the dielectric layers is prevented.

To achieve the above-described objects, the present invention provides a redistribution layer (RDL) suitable for a chip to define the circuit and the contact window required by the following bump process. Wherein, the surface of the chip has at least a bonding pad and a passivation layer, and the upper surface portion of the bonding pad uncovered by the passivation layer forms an opening. The RDL is disposed on the passivation layer and mainly includes a plurality of dielectric layers and at least a conductive layer residing between two dielectric layers adjacent to the conductive layer, wherein the conductive layer is composed of three metal layers, and the three metal layers are laminated from Ti/Al/Ti

According to the embodiment of the present invention, the above-mentioned dielectric layer material includes macromolecule polymer, for example, epoxy resin, polyimide (PI) or BCB.

According to the embodiment of the present invention, the above-mentioned upper-most dielectric layer has at least a contact window to expose the metal layer thereunder. The bottom of a solder bump formed by a following bump process locates in the contact window and is connected to the metal layer.

According to an embodiment of the present invention, the redistribution layer further comprises a under bump metallurgy (UBM) to cover the surface around the contact window, and the UBM is connected between the solder bump and the metal layer.

To achieve the above-described objects, the present invention provides further a circuit structure of a redistribution layer (RDL) suitable for a chip to define the circuit and the contact window required by a following bump process. The RDL is disposed on an active surface of the chip. The circuit structure of the RDL mainly includes a first titanium layer, a second titanium layer of and a conductive layer. Wherein, the material of the conductive layer is aluminum, and the first titanium layer and the second titanium layer cover two surfaces of the conductive layer, respectively.

Since the present invention employs metal layers capable of increasing the connectivity between the conductive layer and the dielectric layer, therefore the connecting reliability of solder bumps formed in a following bump process is significantly enhanced. Furthermore, the peeling or crack caused by poor connectivity between the conductive layer and the adjacent dielectric layers in the prior art are significantly improved thereby. All these contribute to enhance the reliability of a chip package.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a diagram showing circuit structure and a contact window required by re-defining the following bump process using a redistribution layer (RDL) in the prior art.

FIG. 2 is a diagram showing circuit structure and a contact window required by re-defining the following bump process using a redistribution layer (RDL) in an embodiment of the present invention.

### DESCRIPTION OF THE EMBODIMENTS

FIG. 2 is a diagram showing circuit structure and a contact window required by re-defining the following bump process using an RDL 220 in an embodiment of the present invention. Referring to FIG. 2, a passivation layer 204 is disposed on an active surface 202 of a chip 200. The passivation layer 204 is formed by deposition of an organic protective material or inorganic protective material and covers the active surface 202 of the chip 200. The useful material of the passivation layer 204 is, for example, silicon nitride or PSG for protecting the chip 200. The portion of the upper surface of the bonding pad 210 uncovered by the passivation layer 204 forms an opening 206. To better explain the circuit characteristic of the RDL 220, the following description focuses the structure of the RDL 220.

As shown in FIG. 2, the RDL 220 mainly includes a plurality of dielectric layers 222 and 226 and at least a conductive layer 224. Wherein, the conductive layer 224 is disposed between the two adjacent dielectric layers 222 and 226 and electrically connected to the upper surface of the bonding pad 210. The material of the conductive layer 224 is, for example, aluminum, which is the most popular conductive material in the semiconductor process today. Due to excellent conductivity, low price and easy deposition and etching, circuits of the RDL 220 are formed by the normal method of sputtering aluminum on the first dielectric layer 222, followed by lithography etching to define the patterned circuits of the conductive layer 224. In addition to a wet etching or a dry etching, the other appropriate processes can also be used to define the patterned circuits; and the material of the conductive layer 224 is not limited to aluminum only.

Since the connectivity between aluminum and the first dielectric layer 222 made of macromolecule polymer is inherently poor, for improving the connectivity, according to the present invention, a first metal layer 223 made of, for example, titanium or an alloy thereof is formed prior to sputtering aluminum. The connectivity between the first dielectric layer 222 and the first metal layer 223 is much better than the one between aluminum and the first dielectric layer. It is well known that so far titanium is one of few metals with finer, stronger connectivity to the macromolecule polymer, such as polyimide (PI), epoxy resin or BCB. In this way, by means of the characteristic of the first metal layer 223, the connectivity between the first dielectric layer 222 and the conductive layer 224 is improved. Furthermore, the connecting reliability between the two layers is consequently enhanced as the peeling problem is avoided. In addition to titanium, tungsten or the alloy thereof and other metal suicides is also available as the material of the first metal layer 223.

Similarly, the poor connectivity between the conductive layer 224 and the second dielectric layer 226 exists and gives a negative impact on the connecting reliability thereof. As described above, both the second dielectric layer 226 and the first dielectric layer 222 are made of macromolecule polymer. In the embodiment, a second metal layer 225 is disposed between the conductive layer 224 and the second dielectric layer 226. The material of the second metal layer 225 can be titanium, tungsten or other metals with good connectivity to the macromolecule polymer. Wherein, the first metal layer 223 and the second metal layer 225 can be formed on the surface of the conductive layer 224 by means of sputtering or other deposition techniques. The appropriate deposition thickness should be controlled between 2000 Å˜3000 Å or larger. Thus, both the side surfaces of the conductive layer 224 adjacent to the dielectric layer 222 and the dielectric layer 226 are respectively covered by the first metal layer 223 and the second metal layer 225 to strengthen the connecting reliability between the layers.

Next, the formation of a contact window required by the following bump process is described. First, on the photosensitive surface of the second dielectric layer 226, a contact window 228 required by the bump process is defined by means of lithography etching or laser drilling. The contact window 228 exposes a portion of the conductive layer 224 below and the second metal layer 225 thereof. Next, an under bump metallurgy (UBM) 230 with a predetermined thickness is deposited on the surrounding surface around the contact window 228 by means of sputtering. Wherein, to form the UBM 230 a plurality of metal layers is formed in sequence, including an adhesion layer comprised of titanium, tungsten, nickel/vanadium, gold, copper and alloy thereof, a barrier layer and a wetting layer. The UBM serves to strengthen the connecting reliability between the bottom of a solder bump 232 and the redistribution layer (RDL) 220. Finally, after defining the contact window 228 required by the following bump process, the solder bump 232 is formed at the position of the contact window 228 by means of printing or plating, followed by soldering tin and lead etc. on the solder bump 232. Thus, a spherical bump structure is finished, as shown in FIG. 2.

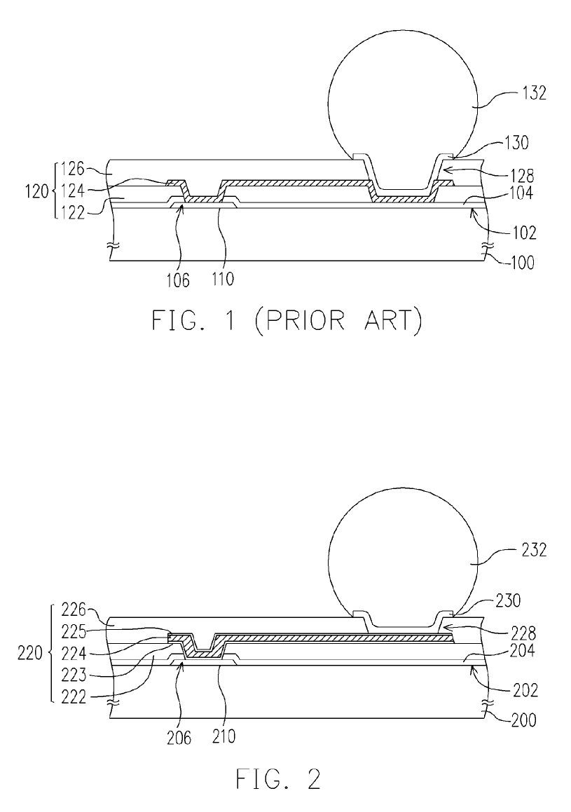

In the embodiment, the connectivity characteristic of the first metal layer 223 and the second metal layer 225 are used to strengthen the connecting reliability between the conductive layer 224 at the bottom of the solder bump 232 and the dielectric layer 222 or 226. Accordingly, the risk of crack occurrence at the contact window 228 and between the conductive layer 224 and the dielectric layer 222 or 226 is remarkably reduced and the connectivity between the solder bump 232 and the RDL 220 is significantly enhanced. In addition, in terms of circuit layout of the RDL 220, since the partial circuit at the bottom of the solder bump 232 is a flat surface, which eliminates need of a recess sunk in the first dielectric layer 222 (as shown in FIG. 1), so that an erosion by etching solvent in the passivation layer 204 on the surface of the chip 200 and the unwanted pinholes or defects caused by erosion and deteriorating the passivation layer 204 are avoided.

The circuit structure comprised of a first metal layer, a conductive layer and a second metal layer provided by the present invention is not limited to be used in the redistribution layer structure of a chip. In fact, the circuit structure can be used in any feasible conductive layer with multi-layer of metal. To obtain the best effect, the first metal layer, the conductive layer and the second metal layer are made of, for example, titanium, aluminum and titanium, respectively. Since titanium is one of few metals with finer, stronger connectivity to the plastic material, such as polyimide (PI), epoxy resin or BCB. In this way, by means of the characteristic of the first metal layer and the second metal layer, the connectivity between the macromolecule polymer and the conductive layer (for example, aluminum) is able to be significantly improved.

In short, the redistribution layer (RDL) and the conductive layer thereof provided by the present invention are superior in the followings.

(1) The peeling problem occurred between a conductive layer and a dielectric layer of the prior art is able to be significantly reduced by disposing the above-described first metal layer and second metal layer, which accordingly contributes to enhance the reliability of a chip package.

(2) The cracking problem occurred between a conductive layer at the bottom of a solder bump and a dielectric layer of the prior art is able to be effectively eliminated by disposing the above-described first metal layer and second metal layer, which accordingly contributes to enhance the reliability of a chip package as well.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A redistribution layer, suitable for a chip to define the circuit and the contact window required by the following bump process, wherein the surface of the chip has at least a bonding pad and a passivation layer, an opening is formed on the upper surface portion of the bonding pad uncovered by the passivation layer, and the redistribution layer disposed on the passivation layer, at least comprising:
a plurality of dielectric layers; and
at least a conductive layer, disposed between the dielectric layers and electrically connected to the bonding pad, wherein the conductive layer is composed of three metal layers, and the three metal layers are laminated from Ti/Al/Ti.

2. The redistribution layer as recited in claim 1, wherein the material of the dielectric layers comprises macromolecule polymer.

3. The redistribution layer as recited in claim 2, wherein the material of the dielectric layers comprises epoxy resin, polyimide (PI) or BCB.

4. The redistribution layer as recited in claim 1, wherein the upper-most layer of the dielectric layers comprises at least a contact window, the contact window exposes the portion of the metal layer thereunder and a solder bump formed in the following bump process, the bottom of the solder bump locates in the contact window and the solder bump connects to the metal layer.

5. The redistribution layer as recited in claim 4, further comprising a under bump metallurgy (UBM), wherein the UBM covers the surrounding surface around the contact window and the UBM is connected between the solder bump and the metal layer.

6. A circuit structure of a redistribution layer, suitable for a chip to define the circuits and the contact window required by the following bump process, wherein the redistribution layer is disposed on the active surface of the chip, comprising at least:
a first titanium layer;
a second titanium layer; and
a conductive layer made of aluminum, wherein the first titanium layer and the second titanium layer cover both the surfaces of the conductive layer, respectively.
